(19) United States
(12) Patent Application Publication
(10) Pub. No.: US 2025/0176151 A1
(43) Pub. Date: May 29, 2025

(54) COMPONENT MOUNTING MACHINE AND COMPONENT MOUNTING METHOD

(71) Applicant: FUJI CORPORATION, Chiryu (JP)

(72) Inventor: Masayoshi MORIYAMA, Gifu-shi (JP)

(73) Assignee: FUJI CORPORATION, Chiryu (JP)

(21) Appl. No.: 18/837,953

(22) PCT Filed: Mar. 30, 2022
(86) PCT No.: PCT/JP2022/015985

§ 371 Date: Feb. 14, 2025

(51) Int. Cl. H05K 13/08; H05K 13/04

(52) U.S. Cl. CPC H05K 13/086; H05K 13/0409; H05K 13/0419; H05K 13/0812; H05K 13/0853; H05K 13/0882; H05K 13/041

(57) ABSTRACT

The component mounter is a component mounter including a mounting control section configured to execute a mounting process based on a control program in which an execution order of a PP cycle including a collection operation of components and a mounting operation of mounting the components on a board is set, a supply control section configured to cause a bulk feeder supplying multiple components in a bulk state to execute a supply operation of the components at a predetermined execution timing, and a timing setting section configured to set the execution timing of the supply operation based on a current collectable quantity and a required time for the supply operation so that, in the PP cycle to be executed, a difference between a required quantity of the components to be collected from the bulk feeder and the collectable quantity of the components in the bulk feeder is not less than a reference value, and waiting time for waiting for completion of the supply operation before execution of the collection operation is minimized.

### TECHNICAL FIELD

The present invention relates to a component mounter and a component mounting method.

### BACKGROUND ART

A component mounter executes a mounting process of mounting components supplied by a feeder or the like on a board. As disclosed in Patent Literature 1, there is a type of feeder described above in which components are supplied in a bulk state in which the components are scattered in a supply region where the components are collectable by a suction nozzle. In a mounting process, a component mounter executes image processing of recognizing a supply state of components by such a bulk feeder, and controls a pickup operation of picking up a component using a suction nozzle based on the result of the image processing.

### CITATION LIST

### Patent Literature

Patent Literature 1: JP-A-2011-114084

### SUMMARY OF THE INVENTION

### Technical Problem

In the mounting process, when a collectable quantity of components supplied by the bulk feeder is less than a required quantity for a collection operation, a part of the scheduled mounting operation cannot be executed, or a supply operation of the bulk feeder may need to wait, potentially leading to a decrease in production efficiency. As described above, when executing the mounting process using the bulk feeder, it is desirable to cause the supply operation to be executed at an appropriate execution timing in consideration of the fact that the collectable quantity of components supplied by the bulk feeder is indefinite.

An object of the present description is to provide a component mounter and a component mounting method capable of preventing a decrease in production efficiency in a mounting process using a bulk feeder.

### Solution to Problem

The present description discloses a component mounter including: a mounting control section configured to execute a mounting process based on a control program in which an execution order of a PP cycle including a collection operation of components and a mounting operation of mounting the components on a board is set: a supply control section configured to cause a bulk feeder supplying multiple components in a bulk state to execute a supply operation of the components at a predetermined execution timing: and a timing setting section configured to set the execution timing of the supply operation based on a current collectable quantity and a required time for the supply operation so that, in the PP cycle to be executed, a difference between a required quantity of the components to be collected from the bulk feeder and the collectable quantity of the components in the bulk feeder is not less than a reference value, and waiting time for waiting for completion of the supply operation before execution of the collection operation is minimized.

The present description discloses a component mounting method including: a mounting control step of executing a mounting process based on a control program in which an execution order of a PP cycle including a collection operation of components and a mounting operation of mounting the components on a board is set: a supply control step of causing a bulk feeder supplying multiple components in a bulk state to execute a supply operation of the components at a predetermined execution timing: and a timing setting step of setting the execution timing of the supply operation based on a current collectable quantity and a required time for the supply operation so that, in the PP cycle to be executed, a difference between a required quantity of the components to be collected from the bulk feeder and the collectable quantity of the components in the bulk feeder is not less than a reference value, and waiting time for waiting for completion of the supply operation before execution of the collection operation is minimized.

### Advantageous Effect of the Invention

With such a configuration of the component mounter and the component mounting method, the execution timing of the supply operation of the bulk feeder is appropriately set based on the required quantity and the collectable quantity. Accordingly, it is possible to prevent occurrences such as insufficient collectable quantity or waiting time for the completion of the supply operation of the bulk feeder, during the execution of the PP cycle. As a result, a decrease in production efficiency can be prevented.

### BRIEF DESCRIPTION OF DRAWINGS

FIG. 1 is a plan view schematically showing a component mounter according to an embodiment.

FIG. 2 is a plan view showing a supply region of components in a bulk feeder.

FIG. 3 is a block diagram showing the component mounter.

FIG. 4 is a diagram showing image data obtained by imaging the supply region.

FIG. 5 is a diagram showing a result of recognition processing of a supply state for the image data in FIG. 4.

FIG. 6 is a table showing a control program and analysis results for each PP cycle.

FIG. 7 is a flowchart showing a mounting process by the component mounter.

FIG. 8 is a flowchart showing a supply management process of the components by the component mounter.

FIG. 9 is a timing chart showing the relationship between PP cycles to be executed and candidates for an execution timing of a supply operation.

FIG. 10 is a flowchart showing waiting time in a PP cycle by the component mounter.

### DESCRIPTION OF EMBODIMENTS

A component mounter and a component mounting method for executing a component mounting process using bulk feeder 30 will be described with reference to the drawings. Bulk feeder 30 is provided on, for example, component mounter 10 that mounts components on board 91, and supplies the components in a bulk state (loose state in which postures of components are irregular).

### 1. Configuration of Component Mounter 10

Component mounter 10 configures a production line for producing board products together with multiple types of board work machines including, for example, another component mounter 10. The board work machines configuring the production line described above can include a printer, an inspection device, a reflow oven, and the like.

### 1-1. Board Conveyance Device

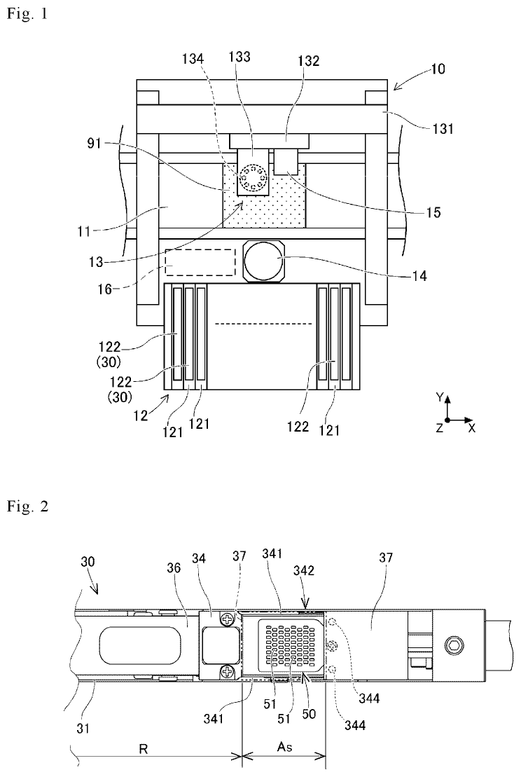

As shown in FIG. 1, component mounter 10 includes board conveyance device 11. Board conveyance device 11 subsequently conveys board 91 in a conveyance direction and positions board 91 at a predetermined position within the mounter.

### 1-2. Component Supply Device 12

Component mounter 10 includes component supply device 12. Component supply device 12 supplies components to be mounted on board 91. Component supply device 12 includes feeders 122 which are provided individually in multiple slots 121. For example, a tape feeder that feeds and moves a carrier tape accommodating a large number of components to supply the components to be collectable is applied to feeder 122. In addition, bulk feeder 30 which supplies components accommodated in a bulk state to be collectable is applied to feeder 122. Details of bulk feeder 30 will be described below.

### 1-3. Component Transfer Device 13

Component mounter 10 includes component transfer device 13. Component transfer device 13 transfers components supplied by component supply device 12 in a predetermined mounting position on board 91. Component transfer device 13 includes head driving device 131, moving table 132, mounting head 133, and suction nozzles 134. Head driving device 131 moves moving table 132 in a horizontal direction (X direction and Y direction) by a linear motion mechanism. Mounting head 133 is detachably fixed to moving table 132 by a clamp member, not shown, and is provided to be movable in the horizontal direction in the mounter.

Mounting head 133 supports multiple suction nozzles 134 to be rotated, and lifted and lowered. Suction nozzle 134 is a holding member that collects and holds a component supplied by feeder 122. Suction nozzle 134 picks up a component supplied by feeder 122 using supplied negative pressure air. As a holding member to be attached to mounting head 133, a chuck or the like that holds the component by gripping the component can be adopted.

### 1-4. Part Camera 14 and Board Camera 15

Component mounter 10 includes part camera 14 and board camera 15. Part camera 14 and board camera 15 are digital imaging devices having imaging elements, such as CMOS. Part camera 14 and board camera 15 execute imaging based on control signals and transmit image data acquired by the imaging. Part camera 14 is configured to image a component held by suction nozzle 134 from below. Board camera 15 is provided on moving table 132 to be movable in the horizontal direction integrally with mounting head 133. Board camera 15 is configured to image board 91 from above.

In addition to using a surface of board 91 as an imaging target, board camera 15 can use various devices or the like as the imaging target as long as various devices are within a movable range of moving table 132. For example, in the present embodiment, as shown in FIG. 2, board camera 15 can image supply region As to which bulk feeder 30 supplies components or fiducial marks 344 provided on an upper part of bulk feeder 30 within the camera's field of view. As described above, board camera 15 can be used commonly to image different imaging targets to acquire the image data used for various pieces of image processing.

### 1-5. Control Device 20

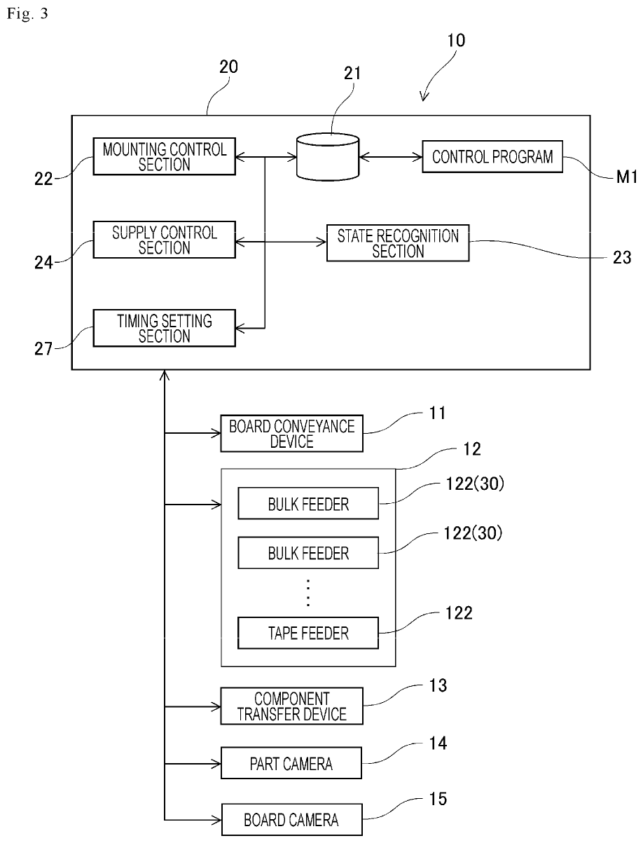

As shown in FIG. 1, component mounter 10 includes control device 20. Control device 20 is mainly made up of CPU, various types of memory, and a control circuit. Control device 20 includes storage section 21 as shown in FIG. 3. Storage section 21 includes an optical drive device such as a hard disk device or a flash memory. Various data such as control program M1 used for controlling a mounting process and the like is stored in storage section 21 of control device 20.

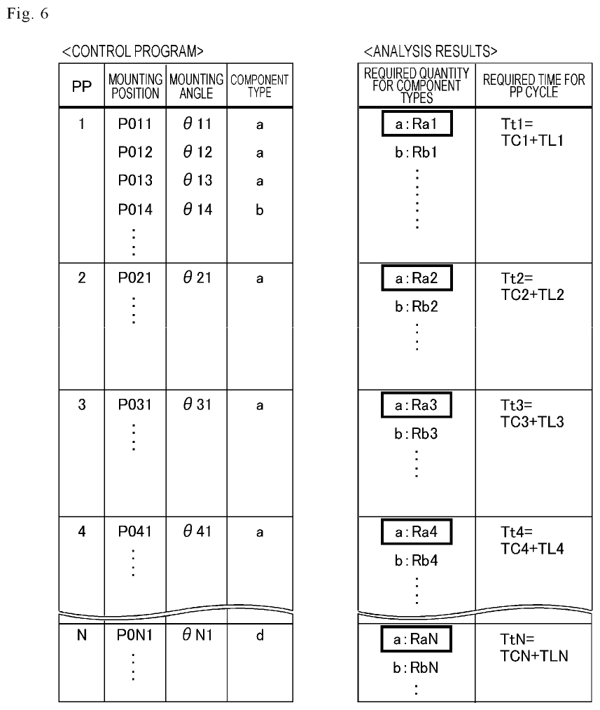

As shown in FIG. 6, control program M1 indicates the mounting position, mounting angle, and component type of the components to be mounted on board 91 in the mounting process in the scheduled mounting order. Here, the mounting process includes a process of repeating a PP cycle (pick-and-place cycle) including a collection cycle and a mounting cycle, multiple times. The “collection cycle” described above is a process of repeating a collection operation by suction nozzle 134 to collect the components supplied by component supply device 12, multiple times.

The “mounting cycle” described above is a process of repeating a mounting operation to mount the collected components at predetermined mounting positions and at predetermined mounting angles on board 91, multiple times. As described above, in control program M1, the execution order (PP1, PP2, and so on) of the PP cycle including multiple collection operations and mounting operations grouped in consideration of the number of suction nozzles 134 supported by mounting head 133, the moving distance of mounting head 133, and the like are set in advance.

Control device 20 includes mounting control section 22. Mounting control section 22 executes the mounting process (mounting control step) based on control program M1 in which the execution order of the PP cycle is set. Mounting control section 22 executes recognition processing of recognizing a holding state of the component held by each of the multiple holding members (suction nozzles 134). Specifically speaking, mounting control section 22 executes image processing on image data acquired by imaging of part camera 14 and recognizes the position and angle of each component with respect to a reference position of mounting head 133. In addition to part camera 14, mounting control section 22 may execute the image processing on the image data acquired by imaging the component by a head camera unit or the like provided integrally with mounting head 133 from side, below, or above.

In the mounting process, mounting control section 22 controls the operation of mounting head 133 based on information output from various sensors, the result of image processing, control program M1, or the like. As a result, the positions and the angles of multiple suction nozzles 134 supported by mounting head 133 are controlled. As a result, the component held by suction nozzle 134 is mounted at a predetermined mounting position instructed by control program M1 at a predetermined mounting angle.

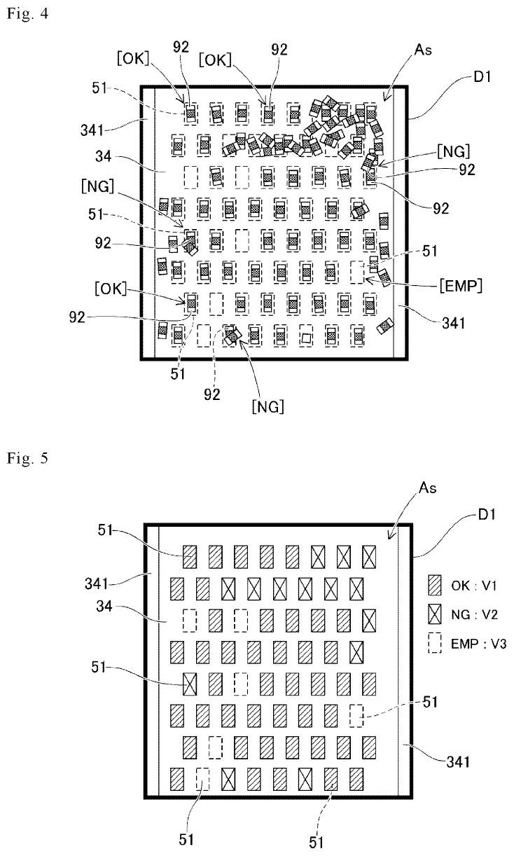

Control device 20 includes state recognition section 23. State recognition section 23 recognizes the supply state of multiple components in supply region As of bulk feeder 30 based on image data D1 (refer to FIG. 4) acquired by the imaging of the camera (in the present embodiment, board camera 15). Recognition processing of the supply state includes a processing step of recognizing whether there are collectable components in supply region As and a processing step of, when there are collectable components, recognizing positions and angles of those components. Moreover, mounting control section 22 controls an operation of mounting head 133 in the collection operation based on a result of the recognition processing of the supply state. Details of the recognition processing by state recognition section 23 will be described later.

Control device 20 includes supply control section 24. Supply control section 24 controls the component supply by component supply device 12. When bulk feeder 30 is provided in component supply device 12, supply control section 24 causes the supply operation by bulk feeder 30 to be executed at an execution timing set by timing setting section 27 described later during the execution of the mounting process (supply control step).

Control device 20 includes timing setting section 27. Timing setting section 27 sets the execution timing of the supply operation by bulk feeder 30 so that, in the PP cycle to be executed, the difference between the required quantity of components 92 to be collected from bulk feeder 30 and the collectable quantity of components 92 in bulk feeder 30 is not less than a reference value (timing setting step). Details of the setting of the execution timing by timing setting section 27 will be described later.

### 2. Configuration of Bulk Feeder 30

Bulk feeder 30 is provided on component mounter 10 and functions as a part of component supply device 12. Bulk feeder 30 supplies components that are accommodated in a bulk state in which the components are not aligned as in a carrier tape. Therefore, since bulk feeder 30 does not use the carrier tape unlike the tape feeder, there is an advantage in that loading of the carrier tape, collection of the used tape, or the like can be omitted.

For example, there is bulk feeder 30 of a type that supplies components in irregular postures to planar supply region As. However, when the components are so close to one another to contact, the components are accumulated (a state of being overlapped in a vertical direction), or the components are in a horizontally standing posture in which the width direction of the component is directed in the vertical direction in supply region As, component mounter 10 cannot regard these components as a collection target. Then, in order to increase a ratio of collectable components, there is bulk feeder 30 of a type that supplies components to supply region As in an aligned state. In the present embodiment, bulk feeder 30 of the type in which the components are aligned will be described as an example.

When bulk feeder 30 is set in slots 121 of component supply device 12, bulk feeder 30 is supplied with power via a connector, and is in a state where bulk feeder 30 can communicate with control device 20. Bulk feeder 30 includes feeder main body 31 formed in a flat box shape. A component case for accommodating multiple components in a bulk state is detachably attached to feeder main body 31. Bulk feeder 30 includes trajectory member 34 which is provided to be capable of vibrating with respect to feeder main body 31. Trajectory member 34 is formed with conveyance path R through which multiple components are conveyed, and supply region As that communicates with conveyance path R and is open upwards such that the multiple components are collectable.

Trajectory member 34 is formed to extend in a front-rear direction (left-right direction in FIG. 2) of feeder main body 31. Pair of side walls 341 protruding upwards is formed on both edges of trajectory member 34 in a width direction (a vertical direction in FIG. 2). Pair of side walls 341 surround the peripheral edge of conveyance path R together with tip end portion 342 of trajectory member 34 to prevent leakage of the components conveyed on conveyance path R. Pair of left and right circular fiducial marks 344 each indicating a reference position of supply region As is affixed to an upper surface of tip end portion 342.

In the present embodiment, alignment member 50 is exchangeably attached to trajectory member 34. Alignment member 50 has multiple cavities 51 that individually accommodate multiple components. Specifically, multiple cavities 51 are arranged in a zigzag shape in which rows adjacent to each other are staggered in the conveyance direction in supply region As. For example, alignment member 50 has 64 cavities 51 in total in which 8 cavities are regularly arranged in the conveyance direction and 8 cavities are regularly arranged in the width direction of conveyance path R. Each of multiple cavities 51 is open upwards to accommodate the component in a posture in which a thickness direction of the component is in the vertical direction. Multiple cavities 51 may be arranged in a matrix.

The opening of cavity 51 is set to a dimension slightly larger than an outer shape of the component as viewed from above. The depth of cavity 51 is set in accordance with the type (shape, mass, or the like) of the component. One trajectory member 34 selected from various types of trajectory members 34 based on the type of component, the required quantity of cavities 51, and the functionality is attached to trajectory member 34.

Here, “supply region As” of trajectory member 34 is a region to which components are supplied in a bulk state, and is a region from which the component is collectable by suction nozzle 134 supported by mounting head 133. In addition, “conveyance path R” of trajectory member 34 is a path of the component along which the component circulated from the component case side to trajectory member 34 is conveyed to supply region As. Cover 36 which covers an upper portion of conveyance path R is fixed to trajectory member 34.

Bulk feeder 30 includes shutter 37 provided on an upper part of trajectory member 34 and capable of closing the opening of supply region As. By opening or closing shutter 37, bulk feeder 30 can prevent the component from protruding and foreign matters from entering supply region As. Shutter 37 is switched between an open state, a closed state, and an intermediate state by an opening/closing operation. The closed state of shutter 37 is a state in which shutter 37 contacts trajectory member 34 and the opening of supply region As is completely closed. At this time, as indicated by dashed lines in FIG. 2, shutter 37 is positioned behind feeder main body 31 with respect to pair of fiducial marks 344 of trajectory member 34, and pair of fiducial marks 344 can be visually recognized and imaged as viewed from above.

The open state of shutter 37 is a state in which the opening of supply region As is not closed and a principal range of supply region As (range in which multiple cavities 51 are provided in the present embodiment) is exposed. At this time, suction nozzle 134 can execute the component collection operation on any of cavities 51. The intermediate state of shutter 37 is a state between the closed state and the open state in which shutter 37 is separated from trajectory member 34 by at least the amplitude of trajectory member 34 vibrated by the excitation, and restricts the protruding of the component from the opening of supply region As. The opening/closing operation of shutter 37 is executed by a driving device (not shown), and shutter 37 is placed in the closed state, the open state, and the intermediate state in accordance with a driving state of the driving device.

Bulk feeder 30 includes an excitation device, not illustrated, provided in feeder main body 31. The excitation device applies vibration to trajectory member 34 so that multiple components are conveyed along conveyance path R. When the excitation device applies vibration to trajectory member 34, trajectory member 34 performs an elliptical motion in the side view. As a result, a forward and upward external force or a rearward and upward external force is applied to multiple components at conveyance path R in accordance with a rotational direction of the elliptical motion of trajectory member 34. As a result, the multiple components are conveyed to the front side or conveyed to the rear side of trajectory member 34. Bulk feeder 30 can vary the conveyance speed of components to be conveyed, the degree of dispersion of components, the conveyance direction, and the like by controlling the frequency and amplitude of the vibration applied to trajectory member 34, and the rotation direction of the elliptical motion caused by the vibration.

The bulk feeder configured as described above receives an instruction to supply components during the mounting process by component mounter 10, for example, during a period from the completion of the current collection operation to the start of the next collection operation, and executes the supply operation of the components. The supply operation of the components is an operation of conveying components to accommodate the components in multiple cavities 51. Specifically, the conveyance operation includes a feed operation in which the components positioned at the front end portion of conveyance path R move forward to the front end of supply region As, followed by a return operation in which the components move backward again to the front end portion of conveyance path R.

When there is sufficient time before the start of the next collection operation, in the conveyance operation, the feed operation and the return operation may be repeatedly executed to cause the multiple components to reciprocate in the front-rear direction multiple times in supply region As. That is, in the supply operation of the components in bulk feeder 30, one pattern selected from multiple patterns can be selectively executed in consideration of the circumstances such as the allowable time and the securement of the collectable quantity.

### 3. Details of State Recognition Section 23

As described above, state recognition section 23 recognizes the supply state of multiple components 92 in supply region As of bulk feeder 30 based on image data D1 (refer to FIG. 4) acquired by the imaging of board camera 15. More specifically, state recognition section 23 first executes the recognition processing of the supply state based on image data D1 acquired by imaging supply region As in a state in which bulk feeder 30 conveys multiple components 92 to supply region As by the vibration.

FIG. 4 shows an example of image data D1. As described above, in supply region As, a large quantity of components 92 in the bulk state are present, and for example, the component accommodated in cavity 51 in a normal posture, the component outside cavity 51, the components that contact each other or deposited on each other, and the component in the horizontal posture can be present. In the present embodiment, state recognition section 23 first calculates a state for each of multiple cavities 51.

Thus, multiple cavities 51 are classified into accommodating cavities (“OK” in FIG. 5) in which components 92 are accommodated to be collectable, NG cavities (“NG” in FIG. 5) in which components 92 are present in the periphery but cannot be collectable, and empty cavities (“EMP” in FIG. 5) in which components 92 are not present in the periphery. FIG. 5 shows the accommodating cavities with diagonal lines, the NG cavities with an X mark formed by diagonal lines, and the empty cavities with only the outline shown in dashed lines. As shown in FIG. 5, state recognition section 23 calculates the numbers (V1, V2, V3) of the states (OK, NG, EMP) of multiple cavities 51.

Then, state recognition section 23 recognizes the current supply state based on the numbers (V1, V2, V3) described above. The supply state may include the ratio of number V1 of accommodating cavities to the total number of cavities 51, the address of accommodating cavities as the position of collectable components 92 (the unique value assigned to each of multiple cavities 51), and the posture of component 92 in the accommodating cavity (the angle of collectable component 92). The ratio of number V1 of accommodating cavities is used, for example, for switching various patterns in the supply operation. In the following description, the “number V1 of accommodating cavities” is also referred to as “collectable quantity V1” of components 92.

### 4. Details of Timing Setting Section 27

Here, when bulk feeder 30 is provided in component supply device 12, as described above, supply control section 24 causes the supply operation by bulk feeder 30 to be executed at an execution timing set by timing setting section 27 (supply control step). Various aspects may be adopted for the execution timing of the supply operation. For example, different execution timings are set when priority is given to reducing the number of executions of the supply operation and when priority is given to reducing the number of executions of the PP cycle including the recovery process that attempts to execute the mounting operation again.

In the present embodiment, timing setting section 27 sets the execution timing with priority given to shortening the required time for the mounting process. Specifically, timing setting section 27 performs control to ensure that the waiting time for waiting for the completion of the supply operation due to the execution of the supply operation does not occur, or even if the waiting time does occur, the waiting time is shortened. In the present embodiment, when the supply operation is executed after completion of the collection operation targeting components 92 supplied by bulk feeder 30, timing setting section 27 sets waiting time Tw from at which the next collection operation targeting same components 92 becomes executable regardless of the progress of the supply operation until the completion of the supply operation.

Timing setting section 27 sets the execution timing so that, in the PP cycle to be executed, the difference between the required quantity of components 92 (for example, required quantity Ra of component type a) to be collected from bulk feeder 30 and the collectable quantity V1 of components 92 in bulk feeder 30 is not less than reference value Vc. Specifically, timing setting section 27 first integrates the required quantity of components 92 for each PP cycle to be executed in the execution order of the PP cycle, and calculates the time when the sum of the integrated value and reference value Vc exceeds current collectable quantity V1 as the execution limit by which the next supply operation to be executed at the latest.

Timing setting section 27 acquires collectable quantity V1 included in the supply state recognized by state recognition section 23, and updates collectable quantity V1 by subtracting the required quantity in the PP cycle from collectable quantity V1 each time the PP cycle is executed. Further, when the supply operation is executed at any timing during the period from the present to the execution limit, timing setting section 27 sets the execution timing such that waiting time Tw for waiting for the completion of the supply operation is minimized before the execution of the collection operation. At this time, timing setting section 27 sets the execution timing of the supply operation based on current collectable quantity V1 and required time Ts of the supply operation.

In the present embodiment, timing setting section 27 considers a completion time of the collection operation targeting components 92 supplied by bulk feeder 30 among multiple PP cycles to be executed as candidates for the execution timing, and sets one or multiple candidates as the execution timing. At this time, as a method of applying any one of the candidates, the following modes can be adopted. In the first application mode, when there are multiple candidates that can be set as the execution timing, timing setting section 27 preferentially sets, as the execution timing, the candidate with a short waiting time that may occur when the supply operation is executed for each candidate. This is a mode of shortening the required time for the mounting process by shortening the waiting time.

In the second application mode, when there are multiple candidates that can be set as the execution timing, timing setting section 27 preferentially sets, as the execution timing, the candidate with the minimum collectable quantity during execution of the supply operation. This reduces the number of executions of the supply operation, thereby reducing the chance of occurrence of the waiting time and consequently shortening the required time for the mounting process. In the third application mode, timing setting section 27 selects one candidate from multiple candidates based on weights set in advance for both the waiting time and the collectable quantity of each candidate described above, and sets the selected one as the execution timing. This is a mode in which, for example, when the difference in waiting times among the candidates is small, the efficiency of the mounting process is further improved by considering the collectable quantity.

When the execution timing of the supply operation is set by timing setting section 27 as described above, supply control section 24 instructs bulk feeder 30 to execute the supply operation when the mounting process proceeds to the execution timing. Reference value Vc can be set as appropriate. For example, reference value Vc is set to be equal to or greater than 1 and equal to or less than the number of suction nozzles 134 supported by mounting head 133.

When supply control section 24 instructs bulk feeder 30 to execute the supply operation as described above, supply control section 24 sends the instruction after the collection operation from bulk feeder 30 is completed and suction nozzle 134 is raised sufficiently. Thus, the supply operation by bulk feeder 30 is executed in parallel with the mounting cycle of the PP cycle.

### 5. Mounting Process by Component Mounter 10

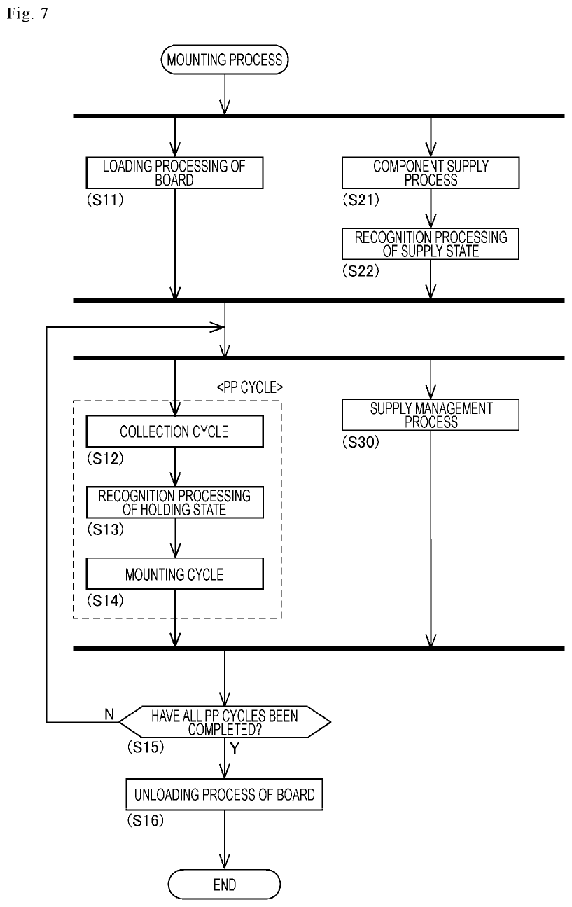

Referring to FIG. 7, a mounting process by component mounter 10 will be described. Here, component supply device 12 is provided with a tape feeder and bulk feeder 30 which are multiple feeders 122. After bulk feeder 30 is set in slots 121, control device 20 executes calibration processing and recognizes the positions of multiple cavities 51 in the mounter.

In the calibration processing described above, control device 20 first moves board camera 15 above pair of fiducial marks 344 of bulk feeder 30, and acquires image data by imaging of board camera 15. Moreover, control device 20 recognizes the position of bulk feeder 30 in the mounter based on the positions of pair of fiducial marks 344 included in the image data by image processing and the position of board camera 15 when the image is captured. Control device 20 can acquire the coordinate values of individual cavities 51 based on a result of the calibration processing and arrangement information of cavities 51.

In the mounting process, first, as shown in FIG. 7, board conveyance device 11 of component mounter 10 executes a loading process of board 91 (S11). As a result, board 91 is loaded into the mounter and positioned at a predetermined position in the mounter. Supply control section 24 executes the supply operation by bulk feeder 30 after S11 or in parallel with S11 (supply control step, S21). By executing the supply operation, multiple components 92 are accommodated in at least a part of multiple cavities 51 of bulk feeder 30. After the supply operation by bulk feeder 30 is completed, state recognition section 23 executes recognition processing of the supply state of components 92 (S22). As a result, current collectable quantity V1 and the position of collectable components 92 (the address of the accommodating cavities) are acquired as the supply state.

Next, control device 20 executes the PP cycle. In the PP cycle, mounting control section 22 executes the collection cycle in which the collection operation of collecting components 92 is repeated using multiple suction nozzles 134 (S12). In this case, mounting control section 22 controls the operation of mounting head 133 in the collection operation such that mounting head 133 is subsequently positioned in accordance with the positions of collectable components 92. In this case, mounting control section 22 appropriately switches the coordinate value that is the center of cavity 51 or the coordinate value of the reference position of component 92 as the position of collectable component 92, and positions suction nozzle 134.

Subsequently, mounting control section 22 executes the recognition processing of the holding state of components 92 held by multiple suction nozzles 134 (S13). Specifically, mounting control section 22 moves mounting head 133 above part camera 14 and sends an imaging command to part camera 14. Mounting control section 22 executes the image processing on the image data acquired by the imaging of part camera 14 to recognize the posture (position and angle) of component 92 held by each of multiple suction nozzles 134. The result of the recognition processing of the holding state (S13) is recorded in storage section 21 as an operation result indicating whether the collection error occurs in the collection operation.

Thereafter, mounting control section 22 executes the mounting cycle in which the mounting operation of mounting the components is repeated using multiple suction nozzles 134 (S14). In the mounting operation of mounting cycle (S14), mounting control section 22 controls the operation of mounting head 133 such that each of components 92 is mounted at the mounting position designated by control program M1. Further, mounting control section 22 controls the operation of mounting head 133 such that suction nozzle 134 is positioned and angled with respect to the mounting position based on the result of the recognition processing (S13).

Supply control section 24 executes the supply management process in parallel with the PP cycle as described above. The supply management process includes the setting of the execution timing of the supply operation of components 92 by bulk feeder 30, the instruction of the supply operation, the recognition processing of the supply state, and the like. For example, when the supply operation of components 92 is executed, the supply operation by bulk feeder 30 is executed in a period from the completion of the collection cycle (S12) of the current PP cycle to the start of the next collection cycle (S12) of the PP cycle.

Control device 20 determines whether all the PP cycles have been completed based on control program M1 (S15). When all PP cycles have not been completed (S15: No), a PP cycle (S12 to S14) as a mounting control step by mounting control section 22 is executed. When all the PP cycles have been completed (S15: Yes), control device 20 executes an unloading process of board 91 (S16). In the unloading process of board 91, board conveyance device 11 unclamps positioned board 91 and then conveys board 91 out of component mounter 10.

### 6. Supply Management Process by Component Mounter 10

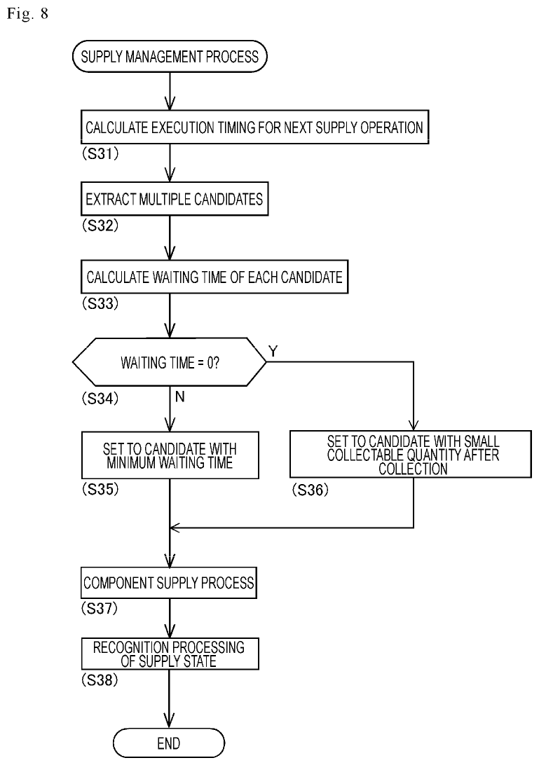

The supply management process by component mounter 10 will be described with reference to FIG. 8. The supply management process of components 92 is executed before the execution of the PP cycle or in parallel with a part of the steps during the execution of the mounting process. First, timing setting section 27 calculates the execution timing for the next supply operation (S31). Timing setting section 27 integrates the required quantity of components 92 for each PP cycle to be executed in the execution order of the PP cycle, and calculates the time when the sum of the integrated value and reference value Vc exceeds current collectable quantity V1 as the execution limit, which serves as the provisional execution timing, by which the next supply operation to be executed at the latest.

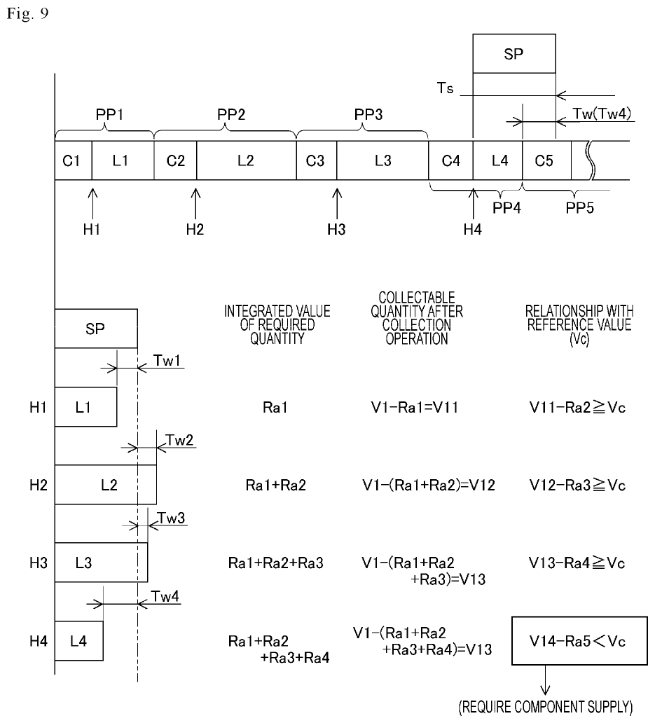

For example, as shown in FIG. 6, control device 20 analyzes control program M1 in advance, and acquires the required quantity (Ra1, Rb1, . . . ) for component types in multiple PP cycles (PP1, PP2, . . . ). FIG. 6 shows required quantity Ra for component type (a) as required quantity Ra1, Ra2, . . . , RaN in each PP cycle (PP1, PP2, . . . , PPN). Then, when the component type (a) is supplied by bulk feeder 30, control device 20, as shown in FIG. 9, integrates required quantity Ra during execution of the first PP cycle (PP1), for example, and calculates the integrated value (Ra1+Ra2+ . . . ).

Further, control device 20 calculates the difference between current collectable quantity V1 and the integrated value as collectable quantities V11 to V14 after the collection operations of multiple PP cycles (PP1 to PP4). Timing setting section 27 calculates the time when the difference between collectable quantities V11 to V14 after the collection operations and required quantities Ra2, Ra3, Ra4, and Ra5 in the next PP cycle is less than reference value Vc as the execution timing of the next supply operation. Here, assuming that the collectable quantity is lower than reference value Vc during the execution of the collection operation of the fifth PP cycle (PP5), since the execution limit is considered to be before the start of the collection operation of the fifth PP cycle (PP5), the execution limit corresponds to the completion time of the collection operation of the fourth PP cycle (PP4).

Next, timing setting section 27 extracts candidates for the execution timing of the supply operation (S32). Specifically, as shown in FIG. 9, timing setting section 27 considers the completion time of the collection operation targeting components 92 supplied by bulk feeder 30 among multiple PP cycles (PP1 to PP4) from the present to the execution limit as candidates H1 to H4 for the execution timing. Subsequently, when there are multiple candidates H1 to H4 that can be set as the execution timing, timing setting section 27 calculates waiting times Tw1 to Tw4 that may occur when the supply operation is executed for each of candidates H1 to H4 (S33). When there is one candidate that can be set as the execution timing, timing setting section 27 may omit the waiting time calculation process (S33).

As shown in FIG. 9, each of waiting times Tw1 to Tw4 corresponds to the difference between the required time for supply operation SP and the required time for mounting operations L1 to L4 of the PP cycles. Timing setting section 27 determines whether calculated waiting times Tw1 to Tw4 include 0 (S34). When calculated waiting times Tw1 to Tw4 don't include 0 (S34: No), timing setting section 27 sets a candidate with minimum waiting time Tw as the execution timing (S35).

On the other hand, when calculated waiting times Tw1 to Tw4 include 0 (S34: No), since there are candidates where the required time for the collection operation is longer than the required time for supply operation SP, timing setting section 27 sets candidate H with waiting time Tw=0 as the execution timing (S36). At this time, when there are multiple candidates with waiting time Tw=0, timing setting section 27 preferentially sets the candidate with the minimum collectable quantity among collectable quantities V11 to V14, that is, the candidate with the later execution order as the execution timing. This aims to consume collectable components 92, which are sufficient in supply region As of bulk feeder 30, thereby reducing the number of executions of the supply operation in the overall mounting process.

As described above, after the timing setting steps (S31 to S36) by timing setting section 27 are completed, supply control section 24 causes bulk feeder 30 to execute the supply operation at the time when the set execution timing is reached (supply control step, S37). After the supply operation by bulk feeder 30 is completed, state recognition section 23 executes recognition processing of the supply state of components 92 (S38). The supply operation (S37) and the recognition processing of the supply state (S38), which are described above, are the same as S21 and S22 executed in parallel with the loading process (S11) of board 91, and thus detailed description thereof will be omitted.

### 7. Effects of Configuration of Embodiment

With such a configuration of component mounter 10 and the component mounting method (FIG. 7), the execution timing of the supply operation of bulk feeder 30 is appropriately set based on the required quantity and collectable quantity V1 (S35 and S36). Accordingly, it is possible to prevent occurrences such as insufficient collectable quantity V1 or waiting time Tw for waiting for the completion of the supply operation of bulk feeder 30, during the execution of the PP cycle. As a result, a decrease in production efficiency can be prevented.

### 8. Modifications of Embodiment

### 8-1. Supply Target of Bulk Feeder 30

In the embodiment, bulk feeder 30 supplies components 92 to be mounted on board 91 by component mounter 10. In the embodiment, a rectangular chip component is exemplified as component 92 described above when viewed from the thickness direction. On the other hand, component 92 is used in a board work machine that executes a predetermined work on board 91, such as component mounter 10, and various articles can be applied as long as the articles can be supplied in a state accommodated in cavity 51 of bulk feeder 30. For example, bulk feeder 30 may supply a solder ball formed in a spherical shape.

### 8-2. Waiting Time and Candidates for Execution Timing of Supply Operation

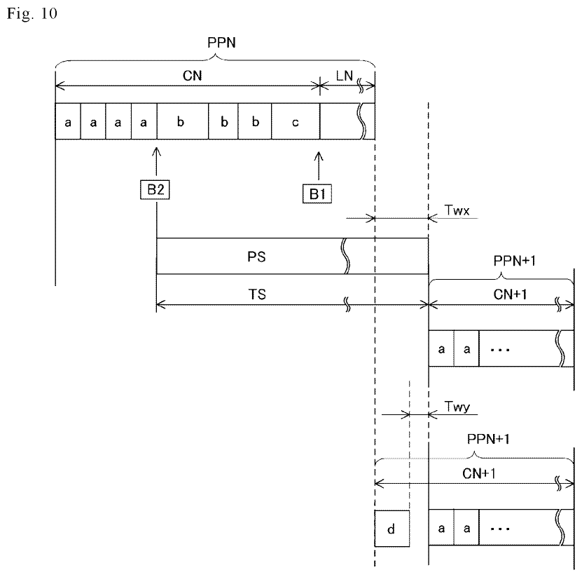

Here, as described above, the waiting time is a time for waiting for the completion of the supply operation due to the execution of the supply operation. In the embodiment, in order to simplify the description, as shown in FIG. 10, it is assumed that the supply operation is started from the completion time (B1) of the collection cycle of the PP cycle, and when the supply operation is not completed by the scheduled start time of the collection cycle of the next PP cycle, waiting time Tw occurs. However, as shown in FIG. 10, when multiple component types (a, b, . . . ) are collected in the collection cycle, it is acceptable to start the supply operation from the completion time (B2) of the collection operation of component type (a) for bulk feeder 30 supplying component type (a).

In addition, when the collection cycle of the next and subsequent PP cycles includes the collection operation targeting component type (a), for example, when the target of the first collection operation is the component type (a), the collection cycle cannot start, thus waiting time Twx for waiting for the completion of supply operation SP occurs. On the other hand, when the collection operation targeting component type (a) is not the first in the collection cycle, for example, a collection operation targeting component type (d) can be executed first, and when supply operation SP is not completed by the start of the collection operation targeting component type (a), waiting time Twy occurs.

As described above, waiting time Tw can be calculated more accurately in consideration of the execution order of the collection operation targeting the component types supplied by bulk feeder 30 within the collection cycle. Similarly, in the embodiment, the candidate for the execution timing of the supply operation is set at the completion time (B1) of the collection cycle, but it may also be set at the completion time (B2) of the collection operation of component type (a) supplied by bulk feeder 30. With such a calculation method, it is possible to more suitably set the execution timing of the supply operation.

### REFERENCE SIGNS LIST

10: component mounter, 11: board conveyance device, 12: component supply device, 122: feeder, 13: component transfer device, 20: control device, 21: storage section, 22: mounting control section, 23: state recognition section, 24: supply control section, 27: timing setting section, 30: bulk feeder, 91: board, 92: component, M1: control program

1. A component mounter comprising:
a mounting control section configured to execute a mounting process based on a control program in which an execution order of a PP cycle including a collection operation of components and a mounting operation of mounting the components on a board is set:
a supply control section configured to cause a bulk feeder supplying multiple components in a bulk state to execute a supply operation of the components at a predetermined execution timing: and
a timing setting section configured to set the execution timing of the supply operation based on a current collectable quantity and a required time for the supply operation so that, in the PP cycle to be executed, a difference between a required quantity of the components to be collected from the bulk feeder and the collectable quantity of the components in the bulk feeder is not less than a reference value, and waiting time for waiting for completion of the supply operation before execution of the collection operation is minimized.

2. The component mounter according to claim 1, wherein the timing setting section is configured to consider a completion time of the collection operation targeting the components supplied by the bulk feeder among multiple PP cycles to be executed as candidates for the execution timing, and set one of the one or multiple candidates as the execution timing.

3. The component mounter according to claim 2, wherein when there are the multiple candidates that can be set as the execution timing, the timing setting section is configured to preferentially set, as the execution timing, the candidate with a short waiting time that may occur when the supply operation is executed for each candidate.

4. The component mounter according to claim 2, or 3, wherein when there are the multiple candidates that can be set as the execution timing, the timing setting section is configured to preferentially set, as the execution timing, the candidate with a minimum collectable quantity during execution of the supply operation.

5. The component mounter according to any one of claims 1 to 4, wherein when the supply operation is executed after completion of the collection operation targeting the components supplied by the bulk feeder, the timing setting section is configured to set the waiting time from at which a next collection operation targeting the same components becomes executable regardless of progress of the supply operation until the completion of the supply operation.

6. A component mounting method comprising:
a mounting control step of executing a mounting process based on a control program in which an execution order of a PP cycle including a collection operation of components and a mounting operation of mounting the components on a board is set:
a supply control step of causing a bulk feeder supplying multiple components in a bulk state to execute a supply operation of the components at a predetermined execution timing: and
a timing setting step of setting the execution timing of the supply operation based on a current collectable quantity and a required time for the supply operation so that, in the PP cycle to be executed, a difference between a required quantity of the components to be collected from the bulk feeder and the collectable quantity of the components in the bulk feeder is not less than a reference value, and waiting time for waiting for completion of the supply operation before execution of the collection operation is minimized.
